(19) United States
(12) Patent Application Publication
(10) Pub. No.: US 2025/0322033 A1
(43) Pub. Date: Oct. 16, 2025

(54) PIPELINED COMPUTE-IN-MEMORY ARCHITECTURES

(71) Applicant: Rain Neuromorphics Inc., San Francisco, CA (US)

(72) Inventors: Mohammed Elneanaei Abdelmoneem Fouda, Alexandria, VA (US); Burak Erbagci, San Jose, CA (US); Cagla Cakir, San Francisco, CA (US)

(21) Appl. No.: 19/075,204

(22) Filed: Mar. 10, 2025

Related U.S. Application Data
(60) Provisional application No. 63/563,790, filed on Mar. 11, 2024.

(51) Int. Cl. G06F 17/16; G06F 7/501; G11C 11/418

(52) U.S. Cl. CPC G06F 17/16; G06F 7/501; G11C 11/418

(57) ABSTRACT

A compute tile is described. The compute tile includes at least one general-purpose processor, a compute tile memory, compute engines, and weight memories corresponding to the compute engines. Each of the compute engines includes a compute-in-memory (CIM) hardware module. The CIM hardware module include storage cells and compute logic coupled with the storage cells. Each of the compute engines is configured to perform a vector-matrix multiplication of an input vector and weights stored in at least one of the storage cells or at least one of the weight memories.

### CROSS REFERENCE TO OTHER APPLICATIONS

This application claims priority to U.S. Provisional Patent Application No. 63/563,790 entitled PIPELINED COMPUTE-IN-MEMORY ARCHITECTURES filed Mar. 11, 2024 which is incorporated herein by reference for all purposes.

### BACKGROUND OF THE INVENTION

Artificial intelligence (AI), or machine learning, utilizes learning networks loosely inspired by the brain in order to solve problems. Learning networks typically include layers of weights that weight signals (mimicking synapses) combined with activation layers that apply functions to the signals (mimicking neurons). The weight layers are typically interleaved with the activation layers. In the forward, or inference, path, an input signal (e.g. an input vector) is propagated through the learning network. In so doing, a weight layer can be considered to multiply input signals (the input vector, or “activation”, for that weight layer) by the weights (or matrix of weights) stored therein and provide corresponding output signals. For example, the weights may be analog resistances or stored digital values that are multiplied by the input current, voltage or bit signals corresponding to the input vector. The weight layer provides weighted input signals to the next activation layer, if any. Neurons in the activation layer operate on the weighted input signals by applying some activation function (e.g. ReLU or Softmax) and provide output signals corresponding to the statuses of the neurons. The output signals from the activation layer are provided as input signals (i.e. the activation) to the next weight layer, if any. This process may be repeated for the layers of the network, providing output signals that are the resultant of the inference. Learning networks are thus able to reduce complex problems to a set of weights and the applied activation functions. The structure of the network (e.g. the number of and connectivity between layers, the dimensionality of the layers, the type of activation function applied), including the value of the weights, is known as the model.

Although a learning network is capable of solving challenging problems, the computations involved in using such a network are often time consuming. For example, a learning network may use millions of parameters (e.g. weights), which are multiplied by the activations to utilize the learning network. Loading and storing weight data is also computationally expensive and can negatively impact throughput and latency. Further, power consumption, particularly for edge devices, is desired to be reduced. Consequently, improvements are still desired.

### BRIEF DESCRIPTION OF THE DRAWINGS

Various embodiments of the invention are disclosed in the following detailed description and the accompanying drawings.

FIGS. 1A-1B depict an embodiment of a portion of a compute engine usable in an accelerator for a learning network and a compute tile with which the compute engine may be used.

FIG. 2 depicts another embodiment of a compute engine usable in an accelerator for a learning network and capable of performing local updates.

FIG. 3 depicts an embodiment of a portion of a compute-in-memory module usable in an accelerator for a learning network.

FIG. 4 depicts an embodiment of a portion of a compute-in-memory module usable in an accelerator for a learning network.

FIGS. 5A-5B depict an embodiment of a compute tile and a pipeline in which

serialized weight-loading may be performed.

FIGS. 6A-6B depict an embodiment of fused multiplex and multiply (FMM) unit and portion of a compute engine in a parallel compute/load architecture.

FIG. 7 depicts an embodiment of an FMM unit in a parallel compute/load architecture with shared adder trees.

FIG. 8 depicts an embodiment of a load and compute unit in a multiplexer-based architecture.

FIG. 9 depicts an embodiment of a compute engine in a multiplexer-based architecture.

FIGS. 10A-10B depict embodiments of techniques for interleaving bit cells.

FIG. 11 depicts an embodiment of SRAM organization.

FIG. 12 depicts an embodiment of a pipeline implementing a parallel compute/load architecture.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Weight loading is expensive and can break the pipeline in many architectures. For example, in some architectures, the compute engines (CEs) are coupled to a compute bus (CB). The CB is coupled to a general-purpose processor (e.g. a RISC-V) and to memory (e.g. static random access memory (SRAM)). In the case that weights are loaded from memory, such as SRAM, to the CEs through the RISC-V, the weight load waits until both the CE and the RISC-V are free to start streaming the weights. This may interrupt pipelining.

Techniques that may facilitate pipelined compute-in-memory architectures are described. In some embodiments, a tile includes compute engines (CEs), at least one general-purpose processor (e.g. a RISC-V), and dedicated weight memory (W-memory). The CEs may be configured to store data and perform vector matrix multiplication (VMM) using the stored data. For example, the CEs may store weights corresponding to a weight matrix and operate on a vector such as an activation. The CEs may store weights in SRAM bit cells that are configured to be used in performing the VMM. The W-memory may load data (e.g. weights) directly to the CEs. Thus, the W-memory may be directly coupled to the CEs. In some embodiments, W-memory includes SRAM (W-SRAM). In some embodiments, a W-SRAM is provided for each CE. Other configurations are possible. The general-purpose processor controls the CEs and may perform nonlinear operations on the output of the CEs. In some embodiments, the storage for a CE is configured analogous to ping-pong buffers. Thus, one weight storage in a CE may be used to perform a VMM while the other weight storage may be loaded (e.g. from the W-SRAM). In addition to the SRAM bit cells, the CEs may include adder trees. In some embodiments, adder trees may be shared and/or may be approximate adder trees. Further, fused multiplex and multiply units may be included in a CE. In some embodiments, the multiplex architecture may be extended further for the adder trees. In some embodiments, the bit cells may share word lines or share bit lines. Use of such an architecture may improve pipelining and may not unduly consume area and/or power.

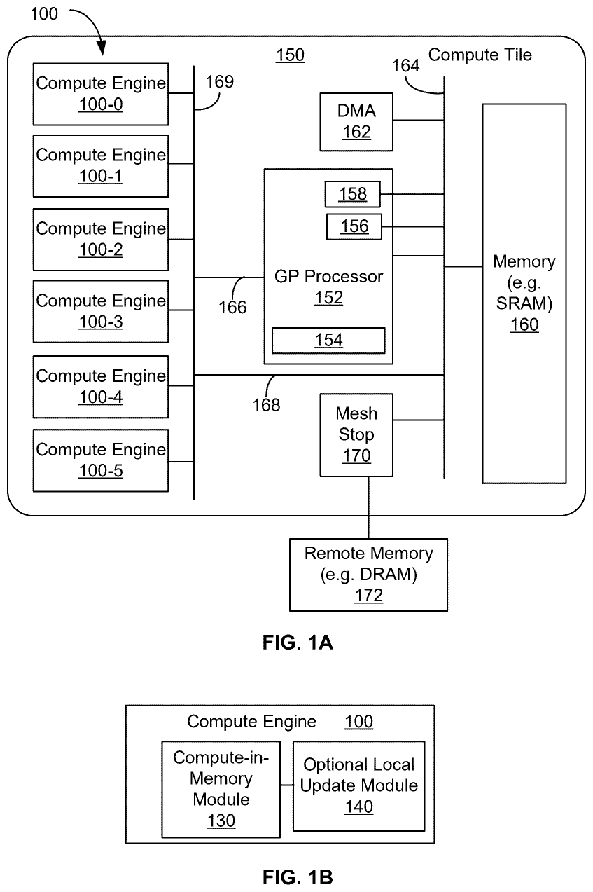

FIGS. 1A-1B depict an embodiment of a portion of compute engine 100 usable in an accelerator for a learning network and compute tile 150 (i.e. an embodiment of the environment) in which the compute engine may be used. FIG. 1A depicts compute tile 150 in which compute engine 100 may be used. FIG. 1B depicts compute engine 100. Compute engine 100 may be part of an AI accelerator that can be deployed for using a model (not explicitly depicted) and, in some embodiments, for allowing for on-chip training of the model (otherwise known as on-chip learning). Referring to FIG. 1A, system 150 is a compute tile and may be considered to be an artificial intelligence (AI) accelerator having an efficient architecture. Compute tile (or simply “tile”) 150 may be implemented as a single integrated circuit. Compute tile 150 includes a general purpose (GP) processor 110 and compute engines 100-0 through 100-5 (collectively or generically compute engines 100) which are analogous to compute engine 100 depicted in FIG. 1A. Also shown are on-tile memory 160 (which may be an SRAM memory) direct memory access (DMA) unit 162, and mesh stop 170. Thus, compute tile 150 may access remote memory 172, which may be DRAM. Remote memory 172 may be used for long term storage. In some embodiments, compute tile 150 may have another configuration. Further, additional or other components may be included on compute tile 150 or some components shown may be omitted. For example, although six compute engines 100 are shown, in other embodiments another number may be included. Similarly, although on-tile memory 160 is shown, in other embodiments, memory 160 may be omitted. GP processor 152 is shown as being coupled with compute engines 100 via compute bus (or other connector) 169 and bus 166. Compute engines 100 are also coupled to bus 164 via bus 168. In other embodiments, GP processor 152 may be connected with compute engines 100 in another manner.

In some embodiments, GP processor 152 is a reduced instruction set computer (RISC) processor. For example, GP processor 152 may be a RISC-V processor or ARM processor. In other embodiments, different and/or additional general purpose processor(s) may be used. The GP processor 152 provides control instructions and, in some embodiments, data to the compute engines 100. GP processor 152 may thus function as part of a control plane for (i.e. providing commands) and is part of the data path for compute engines 100 and tile 150. GP processor 152 may also perform other functions. GP processor 152 may apply activation function(s) to data. For example, an activation function (e.g. a ReLu, Tanh, and/or SoftMax) may be applied to the output of compute engine(s) 100. Thus, GP processor 152 may perform nonlinear operations. GP processor 152 may also perform linear functions and/or other operations. However, GP processor 152 is still desired to have reduced functionality as compared to, for example, a graphics processing unit (GPU) or central processing unit (CPU) of a computer system with which tile 150 might be used.

In some embodiments, GP processor includes an additional fixed function compute block (FFCB) 154 and local memories 156 and 158. In some embodiments, FFCB 154 may be a single instruction multiple data arithmetic logic unit (SIMD ALU). In some embodiments, FFCB 154 may be configured in another manner. FFCB 154 may be a close-coupled fixed-function unit for on-device inference and training of learning networks. In some embodiments, FFCB 154 executes nonlinear operations, number format conversion and/or dynamic scaling. In some embodiments, other and/or additional operations may be performed by FFCB 154. FFCB 154 may be coupled with the data path for the vector processing unit of GP processor 1310. In some embodiments, local memory 156 stores instructions while local memory 158 stores data. GP processor 152 may include other components, such as vector registers, that are not shown for simplicity.

Memory 160 may be or include a static random access memory (SRAM) and/or some other type of memory. Memory 160 may store activations (e.g. input vectors provided to compute tile 150 and the resultant of activation functions applied to the output of compute engines 100). Memory 160 may also store weights. For example, memory 160 may contain a backup copy of the weights or different weights if the weights stored in compute engines 100 are desired to be changed. In some embodiments, memory 160 is organized into banks of cells (e.g. banks of SRAM cells). In such embodiments, specific banks of memory 160 may service specific one(s) of compute engines 100. In other embodiments, banks of memory 160 may service any compute engine 100.

Mesh stop 172 provides an interface between compute tile 150 and the fabric of a mesh network that includes compute tile 150. Thus, mesh stop 172 may be used to communicate with remote DRAM 190. Mesh stop 172 may also be used to communicate with other compute tiles (not shown) with which compute tile 150 may be used. For example, a network on a chip may include multiple compute tiles 150, a GPU or other management processor, and/or other systems which are desired to operate together.

Compute engines 100 are configured to perform, efficiently and in parallel, tasks that may be part of using (e.g. performing inferences) and/or training (e.g. performing inferences and/or updating weights) a model. Compute engines 100 are coupled with and receive commands and, in at least some embodiments, data from GP processor 152. Compute engines 100 are modules which perform vector-matrix multiplications (VMMs) in parallel. Thus, compute engines 100 may perform linear operations. Each compute engine 100 includes a compute-in-memory (CIM) hardware module (shown in FIG. 1A). The CIM hardware module stores weights corresponding to a matrix and is configured to perform a VMM in parallel for the matrix. Compute engines 100 may also include local update (LU) module(s) (shown in FIG. 1A). Such LU module(s) allow compute engines 100 to update weights stored in the CIM. In some embodiments, such LU module(s) may be omitted.

Referring to FIG. 1B, compute engine 100 includes CIM hardware module 130 and optional LU module 140. Although one CIM hardware module 130 and one LU module 140 is shown, a compute engine may include another number of CIM hardware modules 130 and/or another number of LU modules 140. For example, a compute engine might include three CIM hardware modules 130 and one LU module 140, one CIM hardware module 130 and two LU modules 140, or two CIM hardware modules 130 and two LU modules 140.

CIM hardware module 130 is a hardware module that stores data and performs operations. In some embodiments, CIM hardware module 130 stores weights for the model. CIM hardware module 130 also performs operations using the weights. More specifically, CIM hardware module 130 performs vector-matrix multiplications, where the vector may be an input vector provided and the matrix may be weights (i.e. data/parameters) stored by CIM hardware module 130. Thus, CIM hardware module 130 may be considered to include a memory (e.g. that stores the weights) and compute hardware, or compute logic, (e.g. that performs in parallel the vector-matrix multiplication of the stored weights). In some embodiments, the vector may be a matrix (i.e. an n×m vector where n>1 and m>1). For example, CIM hardware module 130 may include an analog static random access memory (SRAM) having multiple SRAM cells and configured to provide output(s) (e.g. voltage(s)) corresponding to the data (weight/parameter) stored in each cell of the SRAM multiplied by a corresponding element of the input vector. In some embodiments CIM hardware module 130 may include a digital static SRAM having multiple SRAM cells and configured to provide output(s) corresponding to the data (weight/parameter) stored in each cell of the digital SRAM multiplied by a corresponding element of the input vector. hardware voltage(s) corresponding to the impedance of each cell multiplied by the corresponding element of the input vector. Other configurations of CIM hardware module 230 are possible. Each CIM hardware module 130 thus stores weights corresponding to a matrix in its cells and is configured to perform a vector-matrix multiplication of the matrix with an input vector.

In order to facilitate on-chip learning, LU module 140 may be provided. LU module 140 is coupled with the corresponding CIM hardware module 130. LU module 140 is used to update the weights (or other data) stored in CIM hardware module 130. LU module 140 is considered local because LU module 140 is in proximity with CIM module 130. For example, LU module 140 may reside on the same integrated circuit as CIM hardware module 130. In some embodiments LU module 140 for a particular compute engine resides in the same integrated circuit as the CIM hardware module 130. In some embodiments, LU module 140 is considered local because it is fabricated on the same substrate (e.g. the same silicon wafer) as the corresponding CIM hardware module 130. In some embodiments, LU module 140 is also used in determining the weight updates. In other embodiments, a separate component may calculate the weight updates. For example, in addition to or in lieu of LU module 140, the weight updates may be determined by a GP processor, in software by other processor(s) not part of compute engine 100 and/or the corresponding AI accelerator, by other hardware that is part of compute engine 100 and/or the corresponding AI accelerator, by other hardware outside of compute engine 100 or the corresponding AI accelerator.

Using compute engine 100 efficiency and performance of a learning network may be improved. Use of CIM hardware modules 130 may dramatically reduce the time to perform the vector-matrix multiplication that provides the weighted signal. Thus, performing inference(s) using compute engine 100 may require less time and power. This may improve efficiency of training and use of the model. LU modules 140 allow for local updates to the weights in CIM hardware modules 130. This may reduce the data movement that may otherwise be required for weight updates. Consequently, the time taken for training may be greatly reduced. In some embodiments, the time taken for a weight update using LU modules 140 may be an order of magnitude less (i.e. require one-tenth the time) than if updates are not performed locally. Efficiency and performance of a learning network provided using system 100 may be increased.

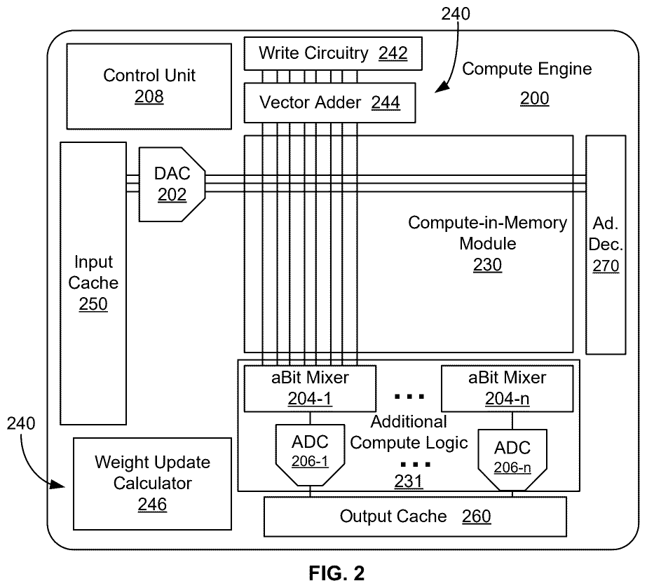

FIG. 2 depicts an embodiment of compute engine 200 usable in an AI accelerator and that may be capable of performing local updates. Compute engine 200 may be a hardware compute engine analogous to compute engine 100. Compute engine 200 thus includes CIM hardware module 230 and optional LU module 240 analogous to CIM hardware modules 130 and LU modules 140, respectively. Compute engine 200 includes input cache 250 (also termed an input buffer 250), output cache 260, and address decoder 270. Additional compute logic 231 is also shown. In some embodiments, additional compute logic 231 includes analog bit mixer (aBit mixer) 204-1 through 204-n (generically or collectively 204), and analog to digital converter(s) (ADC(s)) 206-1 through 206-n (generically or collectively 206). However, for a fully digital CIM hardware module 230, additional compute logic 231 may include logic such as adder trees and accumulators. In some embodiments, at least some of such logic may simply be included as part of CIM hardware module 230. In some embodiments, therefore, the output of CIM hardware module 230 may be provided to output cache 260. Although particular numbers of components 202, 204, 206, 230, 231, 240, 242, 244, 246, 260, and 270 are shown, another number of one or more components 202, 204, 206, 230, 231, 240, 242, 244, 246, 160, and 270 may be present. Further, in some embodiments, particular components may be omitted or replaced. For example, DAC 202, analog bit mixer 204, and ADC 206 may be present only for analog weights.

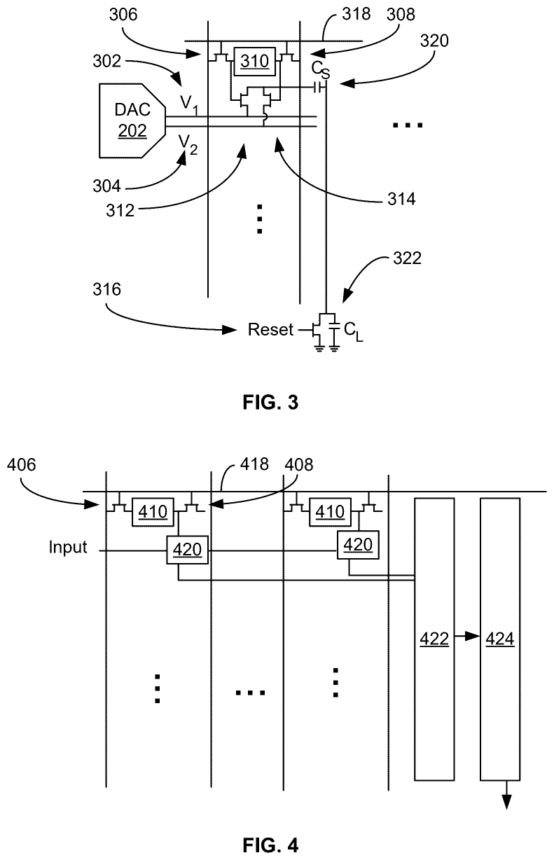

CIM hardware module 230 is a hardware module that stores data corresponding to weights and performs vector-matrix multiplications. The vector is an input vector provided to CIM hardware module 230 (e.g. via input cache 250) and the matrix includes the weights stored by CIM hardware module 230. In some embodiments, the vector may be a matrix. Examples of embodiments CIM modules that may be used in CIM hardware module 230 are depicted in FIGS. 3 and 4.

FIG. 3 depicts an embodiment of a cell in one embodiment of an SRAM CIM module usable for CIM hardware module 230. Also shown is DAC 202 of compute engine 200. For clarity, only one SRAM cell 310 is shown. However, multiple SRAM cells 310 may be present. For example, multiple SRAM cells 310 may be arranged in a rectangular array. An SRAM cell 310 may store a weight or a part of the weight. The CIM hardware module shown includes lines 302, 304, and 318, transistors 306, 308, 312, 314, and 316, capacitors 320 (C_{S}) and 322 (C_{L}). In the embodiment shown in FIG. 3, DAC 202 converts a digital input voltage to differential voltages, V₁ and V₂, with zero reference. These voltages are coupled to each cell within the row. DAC 202 is thus used to temporal code differentially. Lines 302 and 304 carry voltages V₁ and V₂, respectively, from DAC 202. Line 318 is coupled with address decoder 270 (not shown in FIG. 3) and used to select cell 310 (and, in the embodiment shown, the entire row including cell 310), via transistors 306 and 308.

In operation, voltages of capacitors 320 and 322 are set to zero, for example via Reset provided to transistor 316. DAC 202 provides the differential voltages on lines 302 and 304, and the address decoder (not shown in FIG. 3) selects the row of cell 310 via line 318. Transistor 312 passes input voltage V₁ if SRAM cell 310 stores a logical 1, while transistor 314 passes input voltage V₂ if SRAM cell 310 stores a zero. Consequently, capacitor 320 is provided with the appropriate voltage based on the contents of SRAM cell 310. Capacitor 320 is in series with capacitor 322. Thus, capacitors 320 and 322 act as capacitive voltage divider. Each row in the column of SRAM cell 310 contributes to the total voltage corresponding to the voltage passed, the capacitance, C_{S}, of capacitor 320, and the capacitance, C_{L}, of capacitor 322. Each row contributes a corresponding voltage to the capacitor 322. The output voltage is measured across capacitor 322. In some embodiments, this voltage is passed to the corresponding aBit mixer 204 for the column. In some embodiments, capacitors 320 and 322 may be replaced by transistors to act as resistors, creating a resistive voltage divider instead of the capacitive voltage divider. Thus, using the configuration depicted in FIG. 3, CIM hardware module 230 may perform a vector-matrix multiplication using data stored in SRAM cells 310.

FIG. 4 depicts an embodiment of a cell in one embodiment of a digital SRAM module usable for CIM hardware module 230. For clarity, only one digital SRAM cell 410 is labeled. However, multiple cells 410 are present and may be arranged in a rectangular array. Also labeled are corresponding transistors 406 and 408 for each cell, line 418, logic gates 420, adder tree 422 and accumulator 424.

In operation, a row including digital SRAM cell 410 is enabled by address decoder 270 (not shown in FIG. 4) using line 418. Transistors 406 and 408 are enabled, allowing the data stored in digital SRAM cell 410 to be provided to logic gates 420. Logic gates 420 combine the data stored in digital SRAM cell 410 with the input vector. Thus, the binary weights stored in digital SRAM cells 410 are combined with (e.g. multiplied by) the binary inputs. Thus, the multiplication performed may be a bit serial multiplication. The output of logic gates 420 are added using adder tree 422 and combined by accumulator 424. Thus, using the configuration depicted in FIG. 4, CIM hardware module 230 may perform a vector-matrix multiplication using data stored in digital SRAM cells 410.

Referring back to FIG. 2, CIM hardware module 230 thus stores weights corresponding to a matrix in its cells and is configured to perform a vector-matrix multiplication of the matrix with an input vector. In some embodiments, compute engine 200 stores positive weights in CIM hardware module 230. However, the use of both positive and negative weights may be desired for some models and/or some applications. In such cases, the sign may be accounted for by a sign bit or other mapping of the sign to CIM hardware module 230.

Input cache 250 receives an input vector for which a vector-matrix multiplication is desired to be performed. The input vector may be read from a memory, from a cache or register in the processor, or obtained in another manner. For analog cells, such as depicted in FIG. 3, digital-to-analog converter (DAC) 202 may convert a digital input vector to analog in order for CIM hardware module 230 to operate on the vector. Although shown as connected to only some portions of CIM hardware module 230, DAC 202 may be connected to all of the cells of CIM hardware module 230. Alternatively, multiple DACs 202 may be used to connect to all cells of CIM hardware module 230. Address decoder 270 includes address circuitry configured to selectively couple vector adder 244 and write circuitry 242 with each cell of CIM hardware module 230. Address decoder 270 selects the cells in CIM hardware module 230. For example, address decoder 270 may select individual cells, rows, or columns to be updated, undergo a vector-matrix multiplication, or output the results. In some embodiments, aBit mixer 204 combines the results from CIM hardware module 230. Use of aBit mixer 204 may save on ADCs 206 and allows access to analog output voltages. ADC(s) 206 convert the analog resultant of the vector-matrix multiplication to digital form. Output cache 260 receives the result of the vector-matrix multiplication and outputs the result from compute engine 200. Thus, a vector-matrix multiplication may be performed using CIM hardware module 230 and cells 310.

For a digital SRAM CIM module, input cache 250 may serialize an input vector. The input vector is provided to CIM hardware module 230. As previously indicated, DAC 202 may be omitted for a digital CIM hardware module 230, for example which uses digital SRAM storage cells 410. Logic gates 420 combine (e.g., multiply) the bits from the input vector with the bits stored in SRAM cells 410. The output is provided to adder trees 422 and to accumulator 424. In some embodiments, therefore, adder trees 422 and accumulator 424 may be considered to be part of CIM hardware module 230. The resultant is provided to output cache 260. Thus, a digital vector-matrix multiplication may be performed in parallel using CIM hardware module 230.

LU module 240 includes write circuitry 242 and vector adder 244. In some embodiments, LU module 240 includes weight update calculator 246. In other embodiments, weight update calculator 246 may be a separate component and/or may not reside within compute engine 200. Weigh update calculator 246 is used to determine how to update to the weights stored in CIM hardware module 230. In some embodiments, the updates are determined sequentially based upon target outputs for the learning system of which compute engine 200 is a part. In some embodiments, the weight update provided may be sign-based (e.g. increments for a positive sign in the gradient of the loss function and decrements for a negative sign in the gradient of the loss function). In some embodiments, the weight update may be ternary (e.g. increments for a positive sign in the gradient of the loss function, decrements for a negative sign in the gradient of the loss function, and leaves the weight unchanged for a zero gradient of the loss function). Other types of weight updates may be possible. In some embodiments, weight update calculator 246 provides an update signal indicating how each weight is to be updated. The weight stored in a cell of CIM hardware module 230 is sensed and is increased, decreased, or left unchanged based on the update signal. In particular, the weight update may be provided to vector adder 244, which also reads the weight of a cell in CIM hardware module 230. More specifically, adder 244 is configured to be selectively coupled with each cell of CIM hardware module by address decoder 270. Vector adder 244 receives a weight update and adds the weight update with a weight for each cell. Thus, the sum of the weight update and the weight is determined. The resulting sum (i.e. the updated weight) is provided to write circuitry 242. Write circuitry 242 is coupled with vector adder 244 and the cells of CIM hardware module 230. Write circuitry 242 writes the sum of the weight and the weight update to each cell. In some embodiments, LU module 240 further includes a local batched weight update calculator (not shown in FIG. 2) coupled with vector adder 244. Such a batched weight update calculator is configured to determine the weight update.

Compute engine 200 may also include control unit 208. Control unit 208 generates the control signals depending on the operation mode of compute engine 200. Control unit 240 is configured to provide control signals to CIM hardware module 230 and LU module 1549. Some of the control signals correspond to an inference mode. Some of the control signals correspond to a training, or weight update mode. In some embodiments, the mode is controlled by a control processor (not shown in FIG. 2, but analogous to processor 110) that generates control signals based on the Instruction Set Architecture (ISA).

Using compute engine 200, efficiency and performance of a learning network may be improved. CIM hardware module 230 may dramatically reduce the time to perform the vector-matrix multiplication. Thus, performing inference(s) using compute engine 200 may require less time and power. This may improve efficiency of training and use of the model. LU module 240 may perform local updates to the weights stored in the cells of CIM hardware module 230. This may reduce the data movement that may otherwise be required for weight updates. Consequently, the time taken for training may be dramatically reduced. Efficiency and performance of a learning network provided using compute engine 200 may be increased.

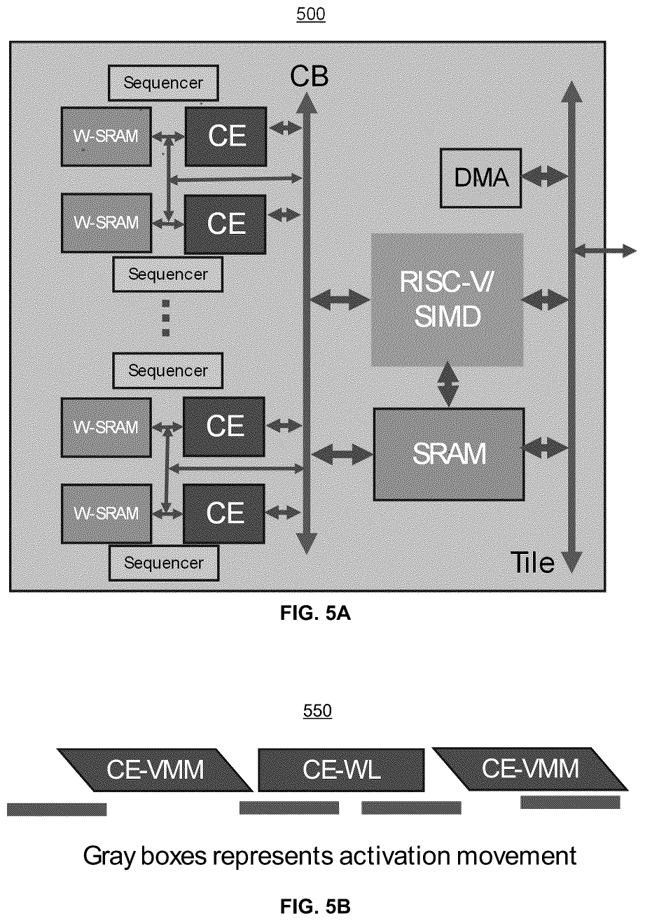

FIGS. 5A-5B depict an embodiment of compute tile 500 (i.e. an embodiment of the environment) and pipeline 550 in which serialized weight-loading may be performed. FIG. 5B depicts an embodiment of pipeline 550. Pipeline 550 contains vector-matrix multiplications performed by the CE (parallelograms CE-VMM), weight loads performed by the CE (rectangles CE-WL), and activation movements (gray boxes). FIG. 5A depicts an embodiment of compute tile 500. In the embodiment shown, CEs are coupled to a general-purpose processor (RISC-V) and on-tile memory (SRAM) via a compute bus (CB). Also shown is a direct memory access (DMA) unit that provides direct memory access, e.g. for communication with another tile (not shown). In addition, small weight memories (W-memories) are present. In the embodiment shown, the W-memories are SRAMs (W-SRAMs) that may be directly coupled to the CEs. In some embodiments, the W-SRAMS are simply coupled to the CEs through a connector other than the CB. In some embodiments, sequencers are also included. Although certain components, certain arrangement of components, and certain numbers of components are shown, in some embodiments some components may be omitted, arranged in a different manner, and/or different numbers of components may be present. For example, another number of CEs and/or W-SRAMs may be present.

Since weights are precompiled and stationary, small W-SRAM(s) are proximate to each CE. In other embodiments, another number of W-SRAMs may be present and/or W-SRAMs may be coupled differently. For example, a W-SRAM might be dedicated to a single CE. The size of these W-SRAMs may be based on the size of the models that supported. In some embodiments, a W-SRAM may be a multiple of single CE capacity (128*128B=16 KB.). In some embodiments, data in the W-SRAM may be loaded directly to CE(s). Thus, data from a W-SRAM need not go through the CB or the RISC-V in order to be loaded to the corresponding CE.

For 128 KB per CE, a total of 1 MB for eight CEs is achieved. This leads to being capable of supporting a 1M parameters model. Weight loads may be performed in parallel to all CEs. Thus, the CEs may be loaded at the same time.

In some embodiments, the weight load is performed while moving the CE results to RISC-V and/or while performing other operations on RISC-V. This may reduce the weight load latency. For example, the weight load latency may be 128 cycles as compared to at least 2000 cycles. Thus, pipelining may be facilitated.

Stationary tensors may be sent directly from the SRAM to W-SRAM. The dynamic tensors and activations may be stored in SRAM.

In some embodiments, there are two mechanisms to control weight swapping: Weights may be written directly into the W-SRAM. A sequencer may be used to load the CEs at certain timestamps. Thus, sequencers are shown in FIG. 5A but may not be present in some embodiments. RISC-V may also initiate the weight load operation through an instruction set architecture with the weight range.

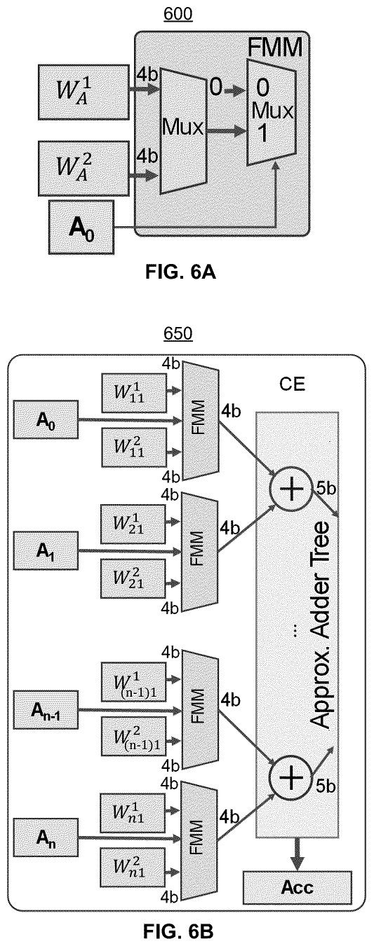

FIGS. 6A-6B depict an embodiment of fused multiplex and multiply (FMM) unit 600 and portion of CE 650 in a parallel compute/load CE architecture. In some embodiments, a compute-in-memory unit includes CEs (e.g., CE 650) having SRAM banks, adder trees, and FMM units (e.g., FMM unit 600). FMM unit 600 is used to select one set of weights (either W¹ or W²) to be multiplied by the input activation. Stated differently, FMM unit 600 selects a bank of CE 650 to be multiplied by the element of the input vector (e.g. the activation element, Aᵢ). In some embodiments, FMM unit 600 is built as one unit to reduce hardware overhead (as shown in CE 650). In the embodiment shown, the elements multiplied by FMM unit 600 are 4 bits wide (indicated as 4b in the figures).

While performing the VMM operation (i.e., multiplying A by W¹), another set of weights (i.e., W²) may be programmed. For example, while A₀ is multiplied by W¹₁₁, W²₁₁ may be programmed (e.g. by loading data from the corresponding W-SRAM(s)). The embodiment thus works in an analogous manner to ping-pong buffers. This allows for dual operation of the CIM unit.

In some embodiments, FMM unit 600 is built with two 2×1 Multiplexers (muxs); a first mux chooses weights to be multiplied and a second mux performs the multiplication by the input. Transmission gate-based multiplexers may be used to provide a lower area footprint. In some embodiments, the first mux in FMM unit 600 selects between W¹ and W². The activation may be used as a selection/control bit for the second mux in FMM unit 600. Thus, the output of FMM unit 600 is a serial multiplication of the bits for appropriate set of weights with the activation.

Doubling the weight memory as in CE 650 could lead to an increase in the area and/or the power. However, in general, adder trees consume much of the power and area of a CE. For example, the adder tree may occupy around 70% of the area and use approximately 80% of the power. Hence, doubling the weight memory may lead to 20% increase in the area and 15% in the power. Consequently, the benefits described herein may be achieved without a significant increase in the power and/or area consumed.

Approximate adders may be used to reduce the overall power and area. Trade-offs may exist between error of approximation and energy, power, and area.

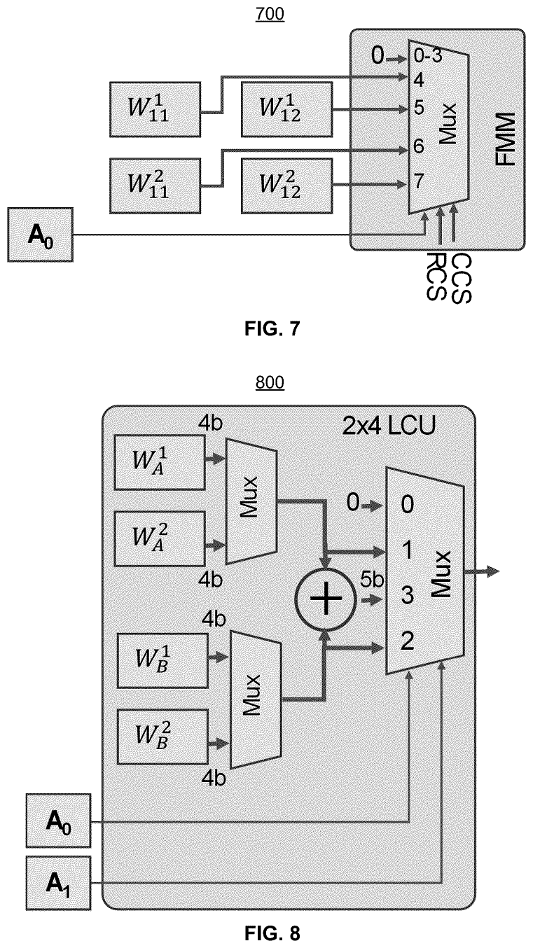

FIG. 7 depicts an embodiment of FMM unit 700 in a parallel compute/load CIM architecture with shared adder trees. Much of the area and power for a CE may be consumed in the adder trees. Hence, sharing the adder trees may reduce the overall power and area utilized by the CE. By combining the two columns and multiplexing the results the system may switch between the columns and rows as shown in FMM unit 700. Table 1 depicts an embodiment of inputs and outputs for the activation, row compute select (RCS) control signal, and column compute select (CCS) control signal.

TABLE 1

| A₀ | RCS | CCS | Output |
|---|---|---|---|
| 0 | x | x | 0 |
| 1 | 0 | 0 | W¹₁₁ |
| | 0 | 1 | W¹₁₂ |
| | 1 | 0 | W²₁₁ |
| | 1 | 1 | W²₁₂ |

FIG. 8 depicts an embodiment of load and compute unit (LCU) 800 in an all mux-based architecture. LCU 800 shows one implementation including two input activations and four weight values.

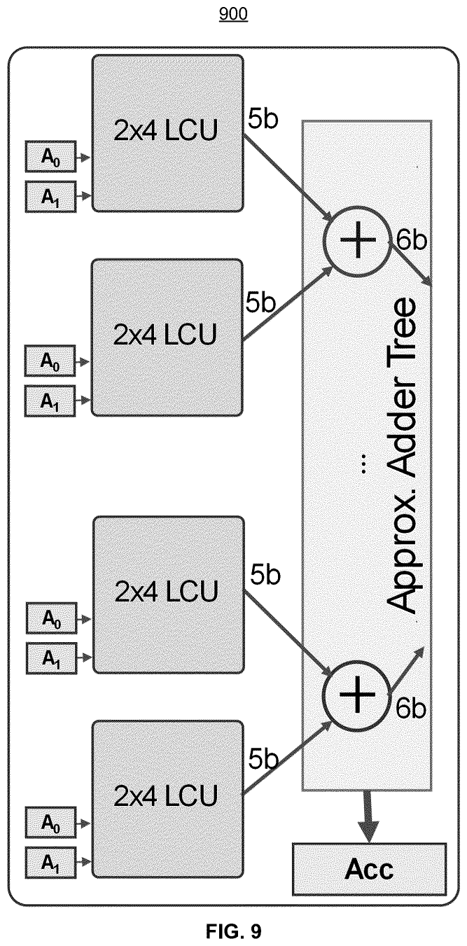

Merging the first layer of the adder tree with the multiplier may reduce the dynamic power consumption, where the inputs become static. Hence, the FMM and the first layer of the adder tree may be implemented with multiplexers, as shown in LCU 800 and in FIG. 9. Table 2 depicts an embodiment of inputs and outputs for LCU 800.

TABLE 2

| Weight | Input | | |
|---|---|---|---|
| Select (s) | InA | InB | Result |
| 0 | 0 | 0 | 0 |
| 0 | 0 | 1 | ${W}_{A}^{1}$ |
| 0 | 1 | 0 | ${W}_{B}^{1}$ |
| 0 | 1 | 1 | ${W}_{A}^{1} + {W}_{B}^{1}$ |
| 1 | 0 | 0 | 0 |
| 1 | 0 | 1 | ${W}_{A}^{2}$ |
| 1 | 1 | 0 | ${W}_{B}^{2}$ |
| 1 | 1 | 1 | ${W}_{A}^{2} + {W}_{B}^{2}$ |

FIG. 9 depicts an embodiment of CE 900 in an all mux-based architecture. 2×4 LCU units (e.g., LCU 800 of FIG. 8) are included in CE 900. Merging the first layer of the adder tree with the multiplier may reduce the dynamic power consumption, where the inputs become static. Hence, the FMM and the first layer of the adder tree may be implemented with multiplexers.

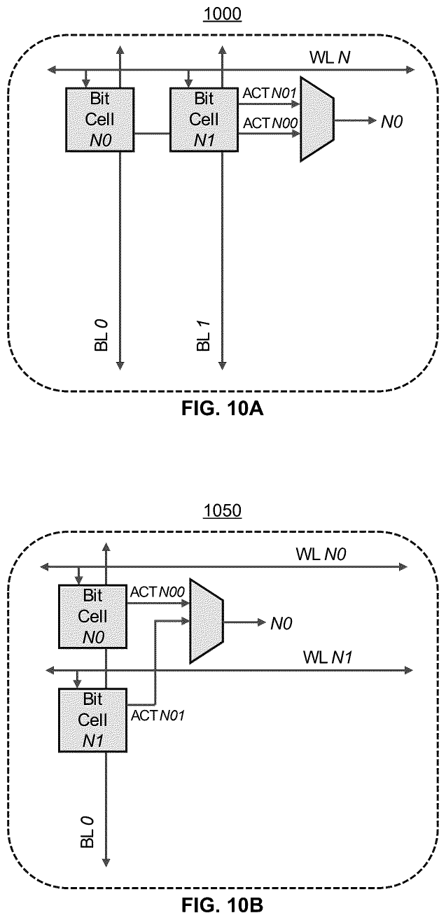

FIGS. 10A-10B depict embodiments of techniques for interleaving bit cells. Embodiment 1000 includes shared word lines (WL N). Embodiment 1050 includes shared bit lines (BL 0). Column multiplexing is an established practice that may be used in providing embodiment 1000. Embodiment 1000 is also suitable for a six-transistor bit cell. In some embodiments, a latch-based bit cell may be modified or replaced with another bit cell. Embodiment 1050 may be tall and narrow due to a large number of columns to support byte operations. In some embodiments, increasing the number of word lines may improve the aspect ratio of embodiment 1050.

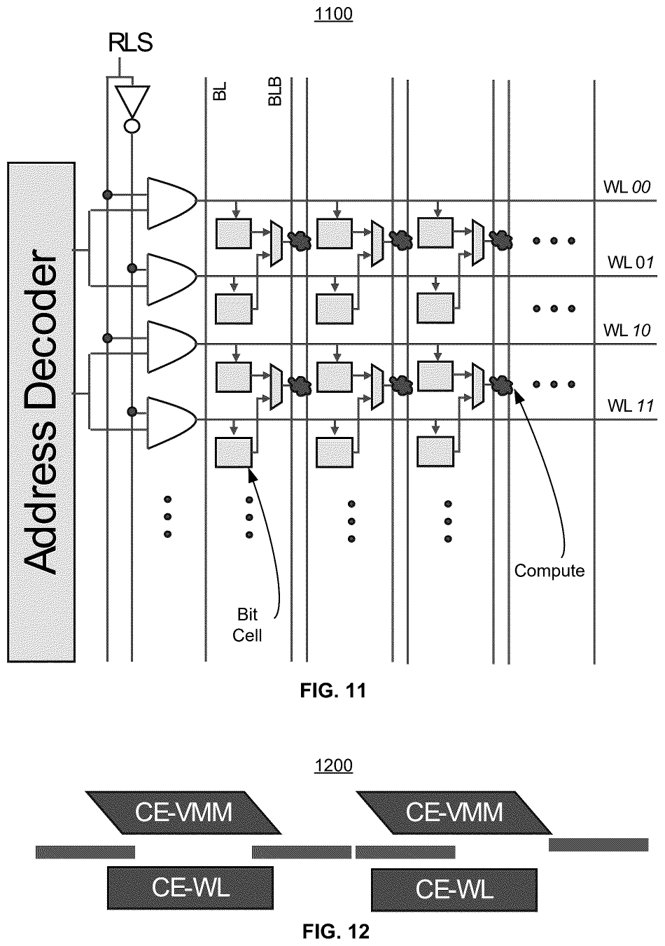

FIG. 11 depicts an embodiment of SRAM organization 1100. In some embodiments, there are two word lines (WL) for every row address. For example, in 1100, WL 00 and WL 01 may correspond to row 0. While WL 00 writes, WL 01 is able to perform a compute-in-memory operation (e.g., a VMM). The row load select (RLS) selects which weights are to be updated. Compute inserted after the bitcell/mux in SRAM organization 1100 may depend on detailed circuit implementation. There may be PPA tradeoffs (e.g., for the amount of compute/logic to be inserted). Table 3 depicts an embodiment of inputs and outputs for SRAM organization 1100.

TABLE 3

| Weights to be | | | |
|---|---|---|---|
| updated | WLᵢ | WLᵢ₀ | WLᵢ₁ |
| 0 | 0 | 0 | 0 |
| 1 | 0 | 0 | 0 |
| 0 | 1 | 1 | 0 |
| 1 | 1 | 0 | 1 |

FIG. 12 depicts an embodiment of pipeline 1200 implementing a parallel compute/load CE architecture. In the example shown, pipeline 1200 is for a single CE accelerator. Pipeline 1200 may be achieved by combining memory near the CIM engine with parallel load and compute features. Pipeline 1200 contains vector-matrix multiplications performed by the CE (parallelograms CE-VMM), weight loads performed by the CE (rectangles CE-WL), and activation movements (unlabeled gray boxes).

Having W-SRAM per CE allows for parallel load and parallel compute of all the CEs. Thus, the system may be fully pipelined, and performance may be enhanced.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A compute tile, comprising:
at least one general-purpose (GP) processor;
a compute tile memory;
a plurality of compute engines, each of the plurality of compute engines including a compute-in-memory (CIM) hardware module, the CIM hardware module including a plurality of storage cells and compute logic coupled with the plurality of storage cells; and
a plurality of weight memories corresponding to the plurality of compute engines;
wherein each of the plurality of compute engines is configured to perform a vector-matrix multiplication (VMM) of an input vector and a plurality of weights stored in at least one of the plurality of storage cells or at least one of the plurality of weight memories.

2. The compute tile of claim 1, wherein each of the plurality of compute engines is further configured to load a second plurality of weights into at least one of the plurality of storage cells from at least one of the plurality of weight memories.

3. The compute tile of claim 2, wherein each of the plurality of compute engines is configured to perform the VMM and load the second plurality of weights in parallel.

4. The compute tile of claim 1, wherein the plurality of compute engines includes at least one adder tree.

5. The compute tile of claim 4, wherein the at least one adder tree is an approximate adder tree.

6. The compute tile of claim 4, wherein the at least one adder tree is shared amongst at least one of the plurality of compute engines.

7. The compute tile of claim 1, wherein the plurality of compute engines includes a plurality of fused multiplex and multiply (FMM) units.

8. The compute tile of claim 7, wherein the plurality of FMM units are merged with at least one adder tree.

9. The compute tile of claim 1, wherein a word line is shared amongst at least one of the plurality of storage cells.

10. The compute tile of claim 1, wherein a bit line is shared amongst at least one of the plurality of storage cells.

11. The compute tile of claim 1, wherein the input vector comprises an input matrix.
